(19) United States
(12) Patent Application Publication
(10) Pub. No.: US 2026/0173288 A1
(43) Pub. Date: Jun. 18, 2026

(54) SERVICE COVER

(71) Applicant: SUMITOMO WIRING SYSTEMS, LTD., Mie (JP)

(72) Inventor: Naoki AOYAMA, Mie (JP)

(21) Appl. No.: 19/129,300

(22) PCT Filed: Oct. 27, 2023
(86) PCT No.: PCT/JP2023/038817

§ 371 Date: May 13, 2025

(30) Foreign Application Priority Data
Nov. 17, 2022 (JP) 2022-184350

(51) Int. Cl. H05K 5/03

(52) U.S. Cl. CPC H05K 5/03

(57) ABSTRACT

A service cover includes a plate-like first resin cover fittable into an opening provided in a case of an electrical device, an annular first sealing member provided on an edge part of the first resin cover and to be held in close contact with the opening, an interlock connector held movably in a direction intersecting a plate thickness direction of the first resin cover on an inner side of the case in the first resin cover and connectable to a terminal in the case, and a metal cover provided to cover an outer side of the case in the first resin cover and including fastening holes fixable to internally threaded portions provided in the case. The metal cover includes a through hole. The first resin cover includes a locking claw for locking the metal cover to the resin cover by being engaged with the through hole.

### TECHNICAL FIELD

The present disclosure relates to a service cover.

### BACKGROUND

Conventionally, some cases of electrical devices are provided with an opening for work and a service cover attachable to and detachable from the opening. Some service covers have a water stop function to hinder the intrusion of a liquid into the case, an interlock function to guarantee an attached state to the opening, and a noise blocking function to block noise (see, for example, Patent Document 1). This service cover has the water stop function by being provided with a plate-like resin cover fittable into the opening and an annular sealing member to be held in close contact with the opening. Further, the service cover has the interlock function by including an interlock connector connectable to a terminal in the case. Further, the service cover has the noise blocking function by including a metal cover provided to cover the resin cover.

### PRIOR ART DOCUMENT

### Patent Document

Patent Document 1: JP 2012-236450 A

### SUMMARY OF THE INVENTION

### Problems to be Solved

However, in the service cover described above, the metal cover was fixed to the resin cover by screws. Thus, there was a problem of increasing the number of components. This leads an increase in component cost caused by the screws and also leads to an increase in manufacturing facility cost and the like for screwing the screws.

The present disclosure aims to provide a service cover capable of suppressing the number of components.

### Means to Solve the Problem

The present disclosure is directed to a service cover with a plate-like resin cover fittable into an opening provided in a case of an electrical device, an annular sealing member provided on an edge part of the resin cover, the sealing member being held in close contact with the opening, an interlock connector held movably in a direction intersecting a plate thickness direction of the resin cover on an inner side of the case in the resin cover, the interlock connector being connectable to a terminal in the case, and a metal cover provided to cover an outer side of the case in the resin cover, the metal cover including a fixing portion fixable to a fixed portion provided in the case, the metal cover including a locked portion, and the resin cover including a locking claw for locking the metal cover to the resin cover by being engaged with the locked portion.

### Effect of the Invention

According to the service cover of the present disclosure, the number of components can be suppressed.

### BRIEF DESCRIPTION OF THE DRAWINGS

FIG. 1 is a side view of a service cover in one embodiment.

FIG. 2 is a perspective view of the service cover in the embodiment.

FIG. 3 is an exploded perspective view of the service cover in the embodiment.

FIG. 4 is a bottom view of the service cover in the embodiment.

FIG. 5 is a partial exploded perspective view of the service cover in the embodiment.

FIG. 6 is a section along 6-6 of FIG. 1.

### DETAILED DESCRIPTION TO EXECUTE THE INVENTION

First, embodiments of the present disclosure are listed and described.

The service cover of the present disclosure is provided with a plate-like resin cover fittable into an opening provided in a case of an electrical device, an annular sealing member provided on an edge part of the resin cover, the sealing member being held in close contact with the opening, an interlock connector held movably in a direction intersecting a plate thickness direction of the resin cover on an inner side of the case in the resin cover, the interlock connector being connectable to a terminal in the case, and a metal cover provided to cover an outer side of the case in the resin cover, the metal cover including a fixing portion fixable to a fixed portion provided in the case, the metal cover including a locked portion, and the resin cover including a locking claw for locking the metal cover to the resin cover by being engaged with the locked portion.

According to this configuration, since the resin cover includes the locking claw for locking the metal cover to the resin cover by being engaged with the locked portion of the metal cover, a screw for fixing the resin cover and the metal cover is unnecessary. Thus, for example, the number of components can be suppressed. Further, for example, a manufacturing facility and the like for screwing screws are unnecessary.

[2] In [1] described above, the locking claw may hold the metal cover movably in a direction intersecting the plate thickness direction of the resin cover.

According to this configuration, since the locking claw holds the metal cover movably in the direction intersecting the plate thickness direction of the resin cover, the resin cover can be normally fit into the opening, for example, while the metal cover is fixed to the case. That is, since the position of the metal cover with respect to the resin cover can be adjusted, for example, even if the positions of the fixed portion and the opening in the case deviate from designed positions, the metal cover and the resin cover can be normally mounted on the case. Thus, a high water stop property can be, for example, ensured by the sealing member. Further, for example, in the case of fixing the resin cover and the metal cover using a screw, it may become impossible to adjust the position of the first resin cover with respect to the metal cover due to a wrong screw tightening torque. However, this can be avoided.

[3] In [1] or [2] described above, the locked portion may be a through hole, and the locking claw may include a plurality of resiliently deformable flexible portions and a plurality of claw portions provided on tip parts of the plurality of flexible portions, the plurality of claw portions expanding to be larger than the through hole when viewed from a penetration direction of the through hole.

According to this configuration, since the locking claw includes the plurality of resiliently deformable flexible portions and the plurality of claw portions provided on the tip parts of the plurality of flexible portions and expanding to be larger than the through hole when viewed from the penetration direction of the through hole, the metal cover can be locked to the resin cover by a simple configuration. For example, the metal cover can be locked to the resin cover while including one through hole.

[4] In [3] described above, the plurality of flexible portions and the plurality of claw portions may be provided at intervals of 90° when viewed from the penetration direction of the through hole.

According to this configuration, since the flexible portions and the claw portions are provided at intervals of 90° when viewed from the penetration direction of the through hole, the metal cover can be locked in a well-balanced manner.

[5] In [3] or [4] described above, the metal cover may include a positioning hole different in size from the through hole, and the resin cover may include a positioning projection to be passed through the positioning hole.

According to this configuration, since the metal cover includes the positioning hole different in size from the through hole and the resin cover includes the positioning projection to be passed through the positioning hole, the erroneous assembly of the resin cover and the metal cover can be, for example, prevented.

### Details of Embodiment of Present Disclosure

A specific example of a service cover of the present disclosure is described below with reference to the drawings. For the convenience of description, some components may be shown in an exaggerated or simplified manner in each drawing. Further, a dimension ratio of each part may be different in each drawing. “Parallel”, “orthogonal” and “perfectly circular” in this specification mean not only strictly parallel, orthogonal and perfectly circular, but also substantially parallel, orthogonal and perfectly circular within a range in which functions and effects in this embodiment are achieved. Note that the present invention is not limited to these illustrations, but is represented by claims and intended to include all changes in the scope of claims and in the meaning and scope of equivalents.

### Configuration of Service Cover 11

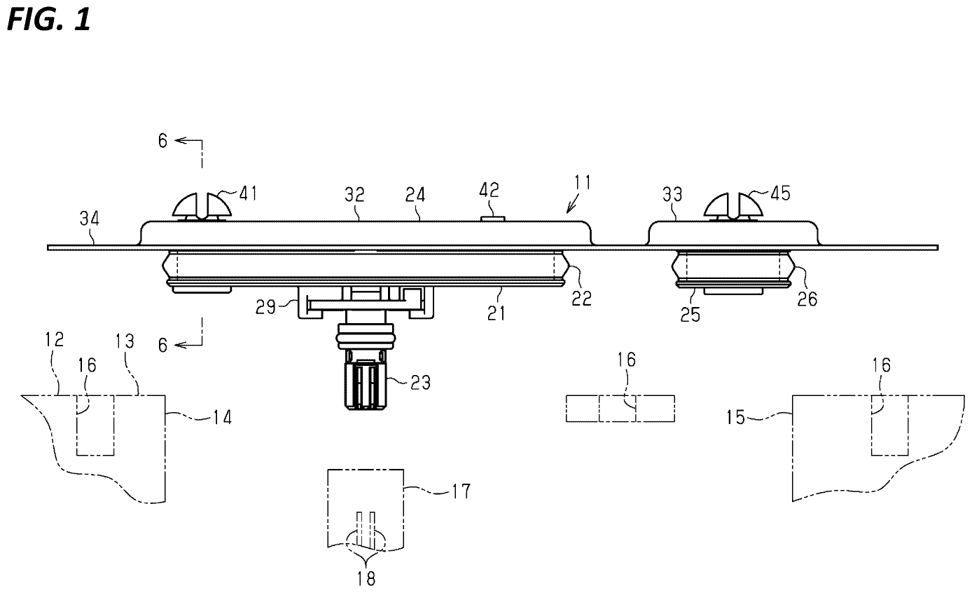

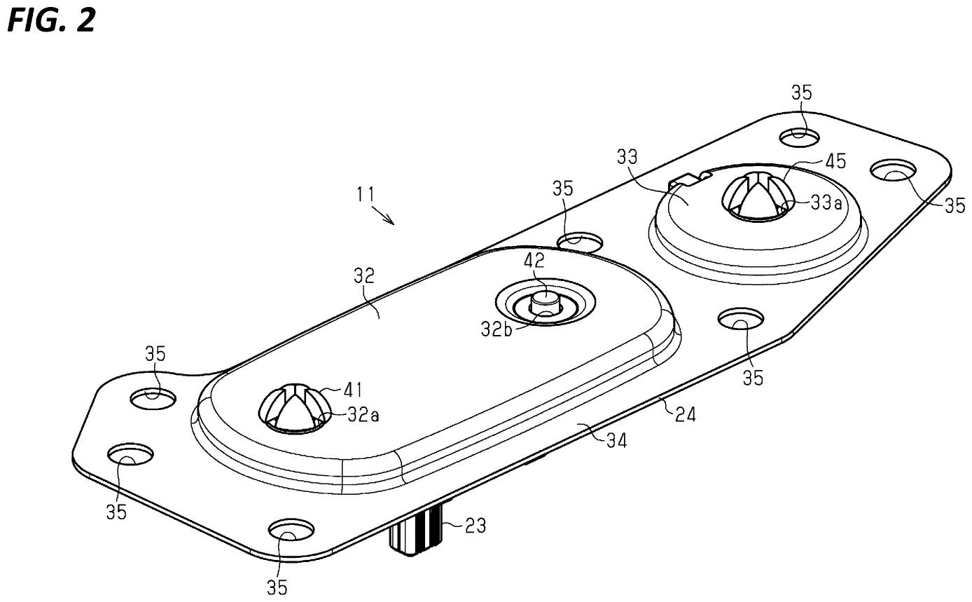

As shown in FIGS. 1 and 2, a service cover 11 is in the form of a rectangular plate as a whole. As shown in FIG. 1, the service cover 11 is provided for a case 13 constituting the outer surface of an electrical device 12. The case 13 includes a first opening 14 and a second opening 15 for work allowing communication between the inside and outside of the case 13 and internally threaded portions 16 serving as a fixed portion provided in the outer surface of the case 13. Note that the first opening 14 is formed into an oval shape, and the second opening 15 is formed into a perfectly circular shape. Further, the electrical device 12 includes a connector 17 inside the case 13. The connector 17 includes a pair of terminals 18. Further, the electrical device 12 includes a plurality of unillustrated connection terminals and the like inside the case 13, and those connection terminals are, for example, so configured that a worker can perform a connecting operation and the like through the first and second openings 14, 15 from the outside of the case 13.

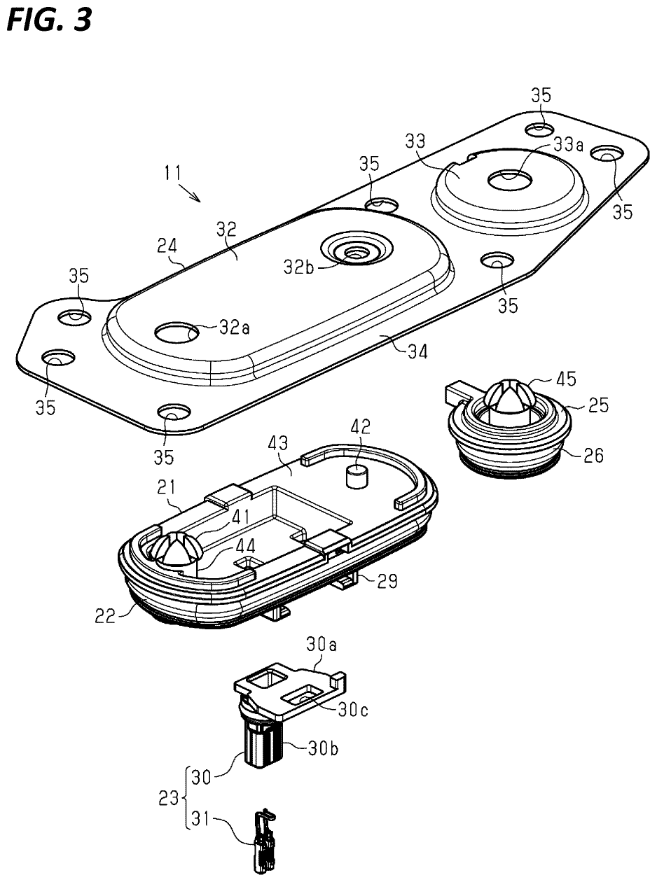

As shown in FIG. 3, the service cover 11 is provided with a first resin cover 21, an annular first sealing member 22, an interlock connector 23 and a metal cover 24. Further, the service cover 11 of this embodiment is provided with a second resin cover 25 and an annular second sealing member 26.

### Configurations of First Resin Cover 21 and First Sealing Member 22

The first resin cover 21 is made of a resin material and in the form of a plate fittable into the first opening 14. The first resin cover 21 is formed into an oval shape in conformity with the shape of the first opening 14. The first sealing member 22 to be held in close contact with the first opening 14 is provided on an edge part of the first resin cover 21.

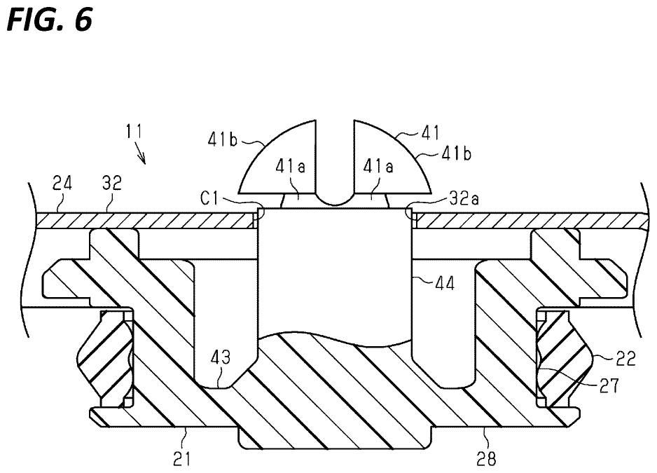

In particular, as shown in FIG. 6, a groove 27 is formed over an entire periphery in the edge part of the first resin cover 21. The first sealing member 22 is fit into the groove 27 from outside. The first sealing member 22 is made of a rubber material.

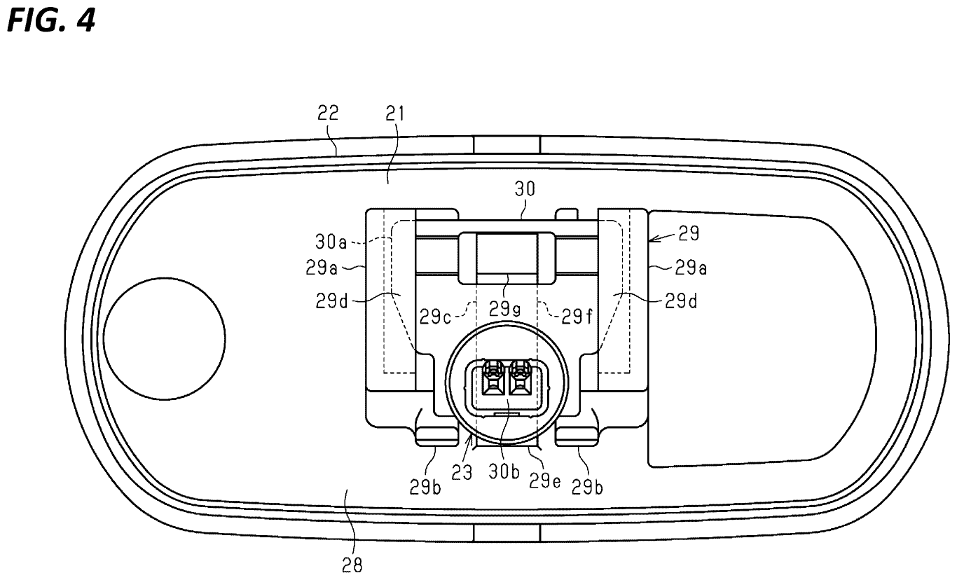

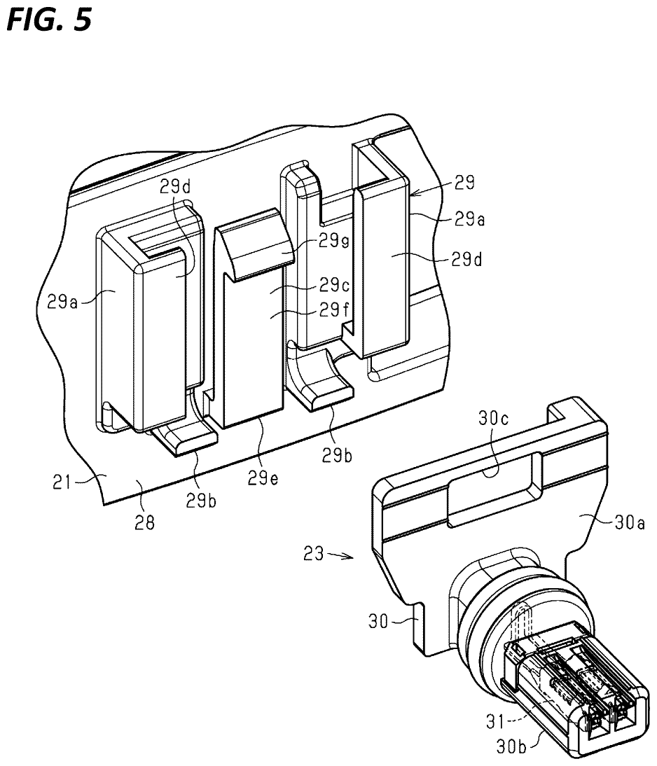

Further, as shown in FIGS. 4 and 5, the first resin cover 21 includes a connector holding portion 29 on a first surface 28 corresponding to an inner side of the case 13. The connector holding portion 29 includes a pair of side walls 29a, a pair of end walls 29b and a holding piece 29c. The pair of side walls 29a include bent walls 29d extending toward each other on tip parts in a projecting direction while projecting from the first surface 28 to extend in parallel to each other along the first surface 28. The pair of end walls 29b project from the first surface 28 at positions corresponding to end parts in a direction in which the pair of side walls 29a extend in parallel. The holding piece 29c is provided between the pair of side walls 29a. The holding piece 29c includes a base portion 29e projecting from the first surface 28 at a position between the pair of end walls 29b, an extending portion 29f extending from the base portion 29e in parallel to the pair of side walls 29a between the pair of side walls 29a and a protrusion 29g projecting in a direction separating from the first surface 28 from the tip of the extending portion 29f. The protrusion 29g is movable in a direction toward the first surface 28 by the deflection of the extending portion 29f.

### Configuration of Interlock Connector 23

As shown in FIGS. 3 and 5, the interlock connector 23 includes a connector housing 30 made of resin and a loop terminal 31. The connector housing 30 includes a plate portion 30a and a connector portion 30b projecting from a principal surface of the plate portion 30a. The plate portion 30a includes an engaging hole 30c penetrating in a plate thickness direction. As shown in FIG. 4, the plate portion 30a is inserted between the pair of side walls 29a and held on the connector holding portion 29 by the protrusion 29g being fit into the engaging hole 30c. The plate portion 30a is held movably in a direction intersecting a plate thickness direction of the first resin cover 21, such as because a width is smaller than an interval between the pair of side walls 29a and the engaging hole 30c is larger than the protrusion 29g. In this way, the position of the interlock connector 23 with respect to the first resin cover 21 is adjustable.

The loop terminal 31 is formed into a U shape. The loop terminal 31 is so accommodated and held in the connector portion 30b that a pair of tip parts are arranged in a tip part of the connector portion 30b. The interlock connector 23 is connected to the connector 17 with the service cover 11 fixed to the case 13. In particular, the pair of tip parts of the loop terminal 31 are connected to the pair of terminals 18 with the service cover 11 fixed to the case 13. In other words, the loop terminal 31 electrically connects the pair of terminals with the service cover 11 fixed to the case 13. The electrical device 12 is configured to allow a large current to flow inside the case 13 based on the electrical connection of the pair of terminals 18. In other words, the electrical device 12 is configured to prohibit a large current from flowing inside the case 13 in a state where the service cover 11 is not fixed to the case 13.

### Configurations of Second Resin Cover 25 and Second Sealing Member 26

As shown in FIG. 1, the second resin cover 25 is made of a resin material and in the form of a plate fittable into the second opening 15. The second resin cover 25 is formed into a perfectly circular shape in conformity with the shape of the second opening 15. The second sealing member 26 to be held in close contact with the second opening 15 is provided on an edge part of the second resin cover 25. In particular, an unillustrated groove is formed over an entire periphery in the edge part of the second resin cover 25, and the second sealing member 26 is fit into the groove from outside. The second sealing member 26 is made of a rubber material.

### Configuration of Metal Cover 24

The metal cover 24 is provided to cover an outer side of the case 13 in the first and second resin covers 21, 25. In particular, as shown in FIGS. 1 and 3, the metal cover 24 includes a first cover portion 32 formed into an oval shape in conformity with the shape of the first resin cover 21 and a second cover portion 33 formed into a perfectly circular shape in conformity with the shape of the second resin cover 25. Further, the metal cover 24 includes a flange portion 34 extending in a flange-like manner while forming tiny steps from the first and second cover portions 32, 33. The second cover portion 33 is arranged at a position separated from the first cover portion 32 along a longitudinal direction of the first cover portion 32. The first and second cover portions 32, 33 are connected by the flange portion 34. The flange portion 34 includes a plurality of fastening holes 35 serving as a fixing portion. The plurality of fastening holes 35 of this embodiment are provided in both end parts in the longitudinal direction of the metal cover 24 and an intermediate part between the first and second cover portions 32, 33 in the longitudinal direction of the metal cover 24. The metal cover 24 is fastened and fixed to the case 13 by unillustrated bolts passed through the fastening holes 35 and threadably engaged with the internally threaded portions 16 of the case 13.

As shown in FIG. 3, the first cover portion 32 includes a through hole 32a serving as a locked portion. The through hole 32a has a perfectly circular shape. Further, the first cover portion 32 includes a positioning hole 32b. The positioning hole 32b has a perfectly circular shape. The positioning hole 32b is different in size from the through hole 32a and has a smaller diameter than the through hole 32a. The through hole 32a is arranged on a side distant from the second cover portion 33 in a longitudinal direction of the first cover portion 32. The positioning hole 32b is arranged on a side near the second cover portion 33 in the longitudinal direction of the first cover portion 32. Further, the second cover portion 33 includes a center hole 33a at a center position. The center hole 33a has a perfectly circular shape.

The first resin cover 21 includes a locking claw 41 for locking the metal cover 24 to the first resin cover 21 by being engaged with the through hole 32a. Further, the first resin cover 21 includes a positioning projection 42 to be passed through the positioning hole 32b.

In particular, as shown in FIG. 6, the first resin cover 21 includes a shaft portion 44 projecting from a second surface 43 corresponding to the outer side of the case 13. The shaft portion 44 may be a cylindrical shaft and has, for example, a perfectly circular shape when viewed from an axial direction. The shaft portion 44 is provided at a position to be passed through the through hole 32a. A diameter of the shaft portion 44 is set to be slightly smaller than that of the through hole 32a. That is, a tiny clearance C1 is set between the outer peripheral surface of the shaft portion 44 and the inner peripheral surface of the through hole 32a.

The locking claw 41 is provided on a tip part of the shaft portion 44. The locking claw 41 includes a plurality of resiliently deformable flexible portions 41a projecting from the shaft portion 44 and claw portion 41b provided on tip parts of the plurality of flexible portions 41a and expanding to be larger than the through hole 32a when viewed from a penetration direction of the through hole 32a. The flexible portions 41a and the claw portions 41 b are provided at intervals of 90° when viewed from the penetration direction of the through hole 32a. In other words, four flexible portions 41a and four claw portions 41b are provided at equal intervals in a circumferential direction when viewed from the penetration direction of the through hole 32a. The claw portions 41b can pass through the through hole 32a by the deflection of the flexible portions 41a. Further, the claw portions 41b are set not to press the metal cover 24 while facing a principal surface of the metal cover 24 in a state passed through the through hole 32a. In this way, the locking claw 41 holds the metal cover 24 movably by an amount corresponding to the clearance C1 in a direction intersecting the plate thickness direction of the first resin cover 21. That is, the position of the first resin cover 21 with respect to the metal cover 24 is adjustable.

Further, as shown in FIG. 3, the positioning projection 42 projects from the second surface 43. The positioning projection 42 may be a cylindrical projection or a cylindrical column and has, for example, a perfectly circular shape when viewed from an axial direction. The positioning projection 42 is provided at a position to be passed through the positioning hole 32b. A diameter of the positioning projection 42 is set to be slightly smaller than that of the positioning hole 32b. That is, a tiny clearance is set between the outer peripheral surface of the positioning projection 42 and the inner peripheral surface of the positioning hole 32b. Thus, the metal cover 24 is slightly movable in a direction intersecting the plate thickness direction of the first resin cover 21.

Further, the second resin cover 25 includes a central locking claw 45 for locking the metal cover 24 to the second resin cover 25 by being engaged with the center hole 33a. The central locking claw 45 is provided at a center position of the second resin cover 25. Since the shapes of the center hole 33a and the central locking claw 45 are the same as those of the through hole 32a and the locking claw 41, these shapes are not described in detail.

Next, functions of the service cover 11 configured as described above are described.

In the case of fixing the service cover 11 to the case 13, the interlock connector 23 is first connected to the connector 17. Subsequently, the first resin cover 21 is fit into the first opening 14 and the second resin cover 25 is fit into the second opening 15. At this time, the first sealing member 22 is held in close contact with the first opening 14 and the second sealing member 26 is held in close contact with the second opening 15, whereby water is stopped at the first and second openings 14, 15.

Further, the positions of the connector 17 and the first opening 14 may deviate from designed positions due to an assembly error or the like. Even in such a case, the position of the interlock connector 23 with respect to the first resin cover 21 can be adjusted, wherefore the first resin cover 21 can be properly fit into the first opening 14 while the interlock connector 23 is connected to the connector 17.

Subsequently, the metal cover 24 is fastened and fixed to the case 13 by the unillustrated bolts threadably engaged with the internally threaded portions 16 of the case 13 through the fastening holes 35 in the metal cover 24.

The positions of the first opening 14 and the internally threaded portions 16 may deviate from designed positions due to a manufacturing error or the like. Even in such a case, the position of the first resin cover 21 with respect to the metal cover 24 can be adjusted, wherefore the first resin cover 21 can be properly fit into the first opening 14 while the metal cover 24 is fixed to the case 13.

Further, the positions of the second opening 15 and the internally threaded portions 16 may deviate from designed positions due to a manufacturing error or the like. Even in such a case, the position of the second resin cover 25 with respect to the metal cover 24 can be adjusted, wherefore the second resin cover 25 can be properly fit into the second opening 15 while the metal cover 24 is fixed to the case 13.

The service cover 11 has the water stop function by including the first and second resin covers 21, 25 fittable into the first and second openings 14, 15 and the annular first and second sealing members 22, 26 to be held in close contact with the first and second openings 14, 15. Further, the service cover 11 has the interlock function by including the interlock connector 23 connectable to the connector 17 in the case 13. Further, the service cover 11 has the noise blocking function by including the metal cover 24 provided to cover the first and second resin covers 21, 25.

Next, effects of the above embodiment are described below.
(1) Since the first resin cover 21 includes the locking claw 41 for locking the metal cover 24 to the first resin cover 21 by being engaged with the through hole 32a in the first cover portion 32 of the metal cover 24, a screw for fixing the first resin cover 21 and the metal cover 24 is unnecessary. Thus, for example, the number of components can be suppressed. Further, a manufacturing facility and the like for screwing screws are unnecessary. Thus, the manufacturing cost of the service cover 11 can be reduced. Note that, since the second resin cover 25 also includes the central locking claw 45 for locking the metal cover 24 to the second resin cover 25 by being engaged with the center hole 33a of the second cover portion 33 in this embodiment, a screw for fixing the second resin cover 25 and the metal cover 24 is also unnecessary.
(2) Since the locking claw 41 holds the metal cover 24 movably in the direction intersecting the plate thickness direction of the first resin cover 21, the first resin cover 21 can be normally fit into the first opening 14, for example, while the metal cover 24 is fixed to the case 13. That is, for example, even if the positions of the internally threaded portions 16 and the first opening 14 deviate from the designed positions, the position of the first resin cover 21 with respect to the metal cover 24 can be adjusted, wherefore the metal cover 24 and the first resin cover 21 can be normally mounted on the case 13. Thus, for example, a high water stop property can be ensured by the first sealing member 22. Further, for example, in the case of fixing the first resin cover 21 and the metal cover 24 using a screw, it may become impossible to adjust the position of the first resin cover 21 with respect to the metal cover 24 due to a wrong screw tightening torque. However, this can be avoided.
(3) The locking claw 41 includes the plurality of resiliently deformable flexible portions 41a and the claw portions 41b provided on the tip parts of the plurality of flexible portions 41a and expanding to be larger than the through hole 32a when viewed from the penetration direction of the through hole 32a of the metal cover 24. Thus, the metal cover 24 can be locked to the first resin cover 21 by a simple configuration. For example, the metal cover 24 can be locked to the first resin cover 21 while including one through hole 32a as in this embodiment.
(4) Since the flexible portions 41a and the claw portions 41b are provided at intervals of 90° when viewed from the penetration direction of the through hole 32a, the metal cover 24 can be locked in a well-balanced manner.
(5) Since the metal cover 24 includes the positioning hole 32b different in size from the through hole 32a and the first resin cover 21 includes the positioning projection 42 to be passed through the positioning hole 32b, the erroneous assembly of the first resin cover 21 and the metal cover 24 can be, for example, prevented.

This embodiment can be modified and carried out as follows. This embodiment and the following modifications can be carried out in combination without technically contradicting each other.
Although the first resin cover 21 includes the shaft portion 44 to be passed through the through hole 32a and the locking claw 41 is provided on the tip part of the shaft portion 44 in the above embodiment, there is no limitation to this and a change can be made to another configuration.
Although the locking claw 41 holds the metal cover 24 movably in the direction intersecting the plate thickness direction of the first resin cover 21 in the above embodiment, there is no limitation to this and a locking claw may be configured to immovably hold the metal cover 24.
Although the locking claw 41 includes the plurality of flexible portions 41a and the claw portions 41b provided on the tip parts of the plurality of flexible portions 41a for one through hole 32a in the above embodiment, there is no limitation to this and another configuration may be adopted. For example, a metal cover may include a plurality of through holes, a first resin cover may include locking claws corresponding to the plurality of respective through holes and the plurality of locking claws may be configured to lock the metal cover by being engaged with the through holes to sandwich the metal cover. Further, although the metal cover 24 includes the through hole 32a serving as a locked portion in the above embodiment, there is no limitation to this and an edge part of a metal cover may be formed into a locked portion and a locking claw may be configured to lock the metal cover by being engaged with the edge part of the metal cover.
Although the flexible portions 41a and the claw portions 41b are provided at intervals of 90° when viewed from the penetration direction of the through hole 32a in the above embodiment, there is no limitation to this and may be, for example, provided at intervals of 180° or 120°.
Although the metal cover 24 includes the positioning hole 32b different in size from the through hole 32a in the above embodiment, there is no limitation to this and a metal cover may include, for example, a positioning hole having the same size as the through hole 32a.
Although the service cover 11 includes the second resin cover 25 and the second sealing member 26 in the above embodiment, there is no limitation to this and the second resin cover 25 and the second sealing member 26 may not be included.
In the shown embodiment, the locking claw 41 of the resin cover 21 is configured to be passed through the metal cover 24 from a bottom surface side of the metal cover 24 toward the top surface of the metal cover 24. According to this configuration, a worker can engage the locking claw 41 with the metal cover 24 by one action of passing the locking claw 41 through the metal cover 24 from the bottom surface side of the metal cover 24 toward the top surface of the metal cover 24, and the metal cover 24 and the resin cover 21 can be easily temporarily fastened.
The locking claw 41 of the shown embodiment can temporarily fasten the metal cover 24 to the resin cover 21 before the metal cover 24 is fixed or fastened to the case 13 of the electrical device 12. If the locking claw 41 can temporarily fasten the metal cover 24, a position deviation of the metal cover 24 with respect to the case 13 of the electrical device 12 can be reduced even without a worker supporting the metal cover 24 with fingers even if the position deviation of the metal cover 24 easily occurs such as when the opening 14 of the case 13 is inclined with respect to a horizontal plane. This is convenient for the worker.
The locking claw 41 of the shown embodiment may be referred to as an eccentric locking claw provided at a non-centered position or an eccentric position of the resin cover 21 in a plan view of the resin cover 21.
As in the shown embodiment, the locking claw 41 may be a single locking claw provided only one for one resin cover 21. Similarly, the central locking claw 45 of the shown embodiment may be a single central locking claw provided only one for one second resin cover 25.
The service cover 11 of the above embodiment may be an in-vehicle service cover to be mounted on a case of an in-vehicle electrical device similarly to the one described in Japanese Patent Laid-Open Publication No. 2012-236450 (Patent Document 1) quoted in this specification by reference.

### LIST OF REFERENCE NUMERALS

11 service cover
12 electrical device
13 case
14 first opening (opening)
15 second opening (opening)
16 internally threaded portion (fixed portion)
17 connector
18 terminal
21 first resin cover (resin cover)
22 first sealing member (sealing member)
23 interlock connector
24 metal cover
25 second resin cover
26 second sealing member
27 groove
28 first surface
29 connector holding portion
29a side wall
29b end wall
29c holding piece
29d bent wall
29e base portion
29f extending portion
29g protrusion
30 connector housing
30a plate portion
30b connector portion
30c engaging hole
31 loop terminal
32 first cover portion
32a through hole (locked portion)
32b positioning hole
33 second cover portion
33a center hole
34 flange portion
35 fastening hole (fixing portion)
41 locking claw
41a flexible portion
41b claw portion
42 positioning projection
43 second surface
44 shaft portion
45 central locking claw
C1 clearance

1. A service cover, comprising:
a plate-like resin cover fittable into an opening provided in a case of an electrical device;
an annular sealing member provided on an edge part of the resin cover, the sealing member being held in close contact with the opening;
an interlock connector held movably in a direction intersecting a plate thickness direction of the resin cover on an inner side of the case in the resin cover, the interlock connector being connectable to a terminal in the case; and
a metal cover provided to cover an outer side of the case in the resin cover, the metal cover including a fixing portion fixable to a fixed portion provided in the case.
the metal cover including a locked portion, and
the resin cover including a locking claw for locking the metal cover to the resin cover by being engaged with the locked portion.

2. The service cover of claim 1, wherein the locking claw holds the metal cover movably in a direction intersecting the plate thickness direction of the resin cover.

3. The service cover of claim 1, wherein:
the locked portion is a through hole, and
the locking claw includes a plurality of resiliently deformable flexible portions and a plurality of claw portions provided on tip parts of the plurality of flexible portions, the plurality of claw portions expanding to be larger than the through hole when viewed from a penetration direction of the through hole.

4. The service cover of claim 3, wherein the plurality of flexible portions and the plurality of claw portions are provided at intervals of 90° when viewed from the penetration direction of the through hole.

5. The service cover of claim 3, wherein:
the metal cover includes a positioning hole different in size from the through hole, and the resin cover includes a positioning projection to be passed through the positioning hole.
